(19) United States
(12) Patent Application Publication
(10) Pub. No.: US 2018/0248065 A1
(43) Pub. Date: Aug. 30, 2018

(54) PHOTOVOLTAIC DEVICE, PHOTOVOLTAIC CELL, AND PHOTOVOLTAIC MODULE

(71) Applicant: NANOBIT TECH. CO., LTD., Taoyuan City (TW)

(72) Inventors: YU-YANG CHANG, Taoyuan City (TW); DING-KUO DING, Taoyuan City (TW); SHIOU-MING LIU, Taoyuan City (TW); SUNG-CHIEN HUANG, Taoyuan City (TW); CHING-KAI CHO, Taoyuan City (TW)

(21) Appl. No.: 15/859,887

(22) Filed: Jan. 2, 2018

(30) Foreign Application Priority Data
Feb. 24, 2017 (TW) 106202797

(51) Int. Cl. H01L 31/05; H01L 31/02; H01L 31/049

(52) U.S. Cl. CPC H01L 31/0508; H01L 31/0512; H01L 31/049; H01L 31/02008

(57) ABSTRACT

A photovoltaic cell of the present disclosure includes a substrate, a plurality of conductive sheets mutually intervening disposed on the substrate and forming a first matrix arrangement, and a plurality of photovoltaic units mutually intervening disposed on the conductive sheets and forming a second matrix arrangement different from the first matrix arrangement. Moreover, any two adjacent rows of the second matrix arrangement of the photovoltaic units are separated from each other. In each row of the photovoltaic units, an electrical connection of any two adjacent photovoltaic units is established by being connected to one of the conductive sheets. Accordingly, the structure of the photovoltaic cell of the present disclosure can be massively manufactured.

### BACKGROUND OF THE INVENTION

### 1. Field of the Invention

The present disclosure relates to a solar battery; in particular, to a photovoltaic device, a photovoltaic cell, and a photovoltaic module.

### 2. Description of Related Art

Solar energy is an inexhaustible and renewable energy in nature, and solar energy obtained from a photovoltaic cell does not produce any pollution, so that solar energy is friendly to the environment as compared to fossil fuels, and the development of photovoltaic cell is important in renewable energy. The initial drawbacks in the development of photovoltaic cell are the low photoelectric conversion efficiency and the high cost, accordingly, organic photovoltaic cell by using polymer materials draw the industrial and academic domains' attention because of the properties such as lower manufacturing cost, lighter material and flexible. However, the structure of conventional photovoltaic cell is too complicated, which results in the difficulty for mass production.

### SUMMARY OF THE INVENTION

The present disclosure provides a photovoltaic device, a photovoltaic cell, and a photovoltaic module to solve the drawbacks of conventional photovoltaic cells.

The present disclosure discloses a photovoltaic cell, which includes a substrate, a plurality of conductive sheets mutually interveningly disposed on the substrate and forming a first matrix arrangement, and a plurality of photovoltaic units mutually interveningly disposed on the conductive sheets and forming a second matrix arrangement different from the first matrix arrangement. Any two adjacent rows of the second matrix arrangement of the photovoltaic units are separated from each other. In each row of the photovoltaic units, an electrical connection of any two adjacent photovoltaic units is established by being connected to one of the conductive sheets.

Preferably, each of the photovoltaic units includes a photoelectric conversion complex layer, a conductive pillar, an insulating film, and a connecting sheet. The photoelectric conversion complex layer includes a first region, a second region, and a partition slot arranged between the first region and the second region. The first region and the second region are separated from each other and are respectively disposed on two adjacent conductive sheets. The conductive pillar is embedded in the second region and is connected to the corresponding conductive sheet. The insulating film is disposed on the first region and the second region and is arranged across the partition slot. The connecting sheet is disposed on the first region and the second region and is connected to the conductive pillar. The insulating film is embedded in the connecting sheet.

Preferably, the first region and the second region respectively arranged in any two adjacent photovoltaic units and arranged adjacent to each other are disposed on the one of the conductive sheets.

Preferably, in each of the photovoltaic units, the second region is divided into two sub-regions by the conductive pillar embedded therein, and a distance between the two sub-regions is substantially within a range of 10 μm to 120 μm.

Preferably, in each of the photovoltaic units, a distance between the first region and the second region is substantially within a range of 10 μm to 120 μm, and each of the first region and the second region includes an electron transferring layer, an active layer stacked on the electron transferring layer, and an electronic hole transferring layer stacked on the active layer.

Preferably, a distance between any two adjacent photovoltaic units is substantially within a range of 10 μm to 120 μm.

Preferably, the substrate includes a plate and a hardened layer disposed on the plate, and the conductive sheets are disposed on the hardened layer.

Preferably, the plate is a translucent resin plate or a translucent glass plate, and the material of the translucent resin plate includes at least one of a polyethylene terephthalate (PET), a polyethylene (PE), a polyimide (PI), a polyamide (PA), a polyurethane (PU), and an acrylic.

Preferably, the material of the hardened layer includes at least one of an acrylic, an epoxy, and a silica, and the hardened layer has a thickness within a range of 1 μm to 5 μm.

Preferably, each of the conductive sheets is transparent and is made of an organic conductive material or an inorganic conductive material, wherein the organic conductive material includes a poly 3,4-ethylenedioxythiophene (PEDOT), carbon nanotubes, or a combination thereof, and the inorganic conductive material includes a metal or a metal oxide.

The present disclosure also discloses a photovoltaic device, which includes a photovoltaic cell, two protective layers, and a package compound. The photovoltaic cell includes a substrate, a plurality of conductive sheets mutually interveningly disposed on the substrate and forming a first matrix arrangement, and a plurality of photovoltaic units mutually interveningly disposed on the conductive sheets and forming a second matrix arrangement different from the first matrix arrangement. Any two adjacent rows of the second matrix arrangement of the photovoltaic units are separated from each other; in each row of the photovoltaic units, an electrical connection of any two adjacent photovoltaic units is established by being connected to one of the conductive sheets. The two protective layers are respectively disposed on two opposite sides of the photovoltaic cell. The package compound connects the two protective layers and is arranged around the photovoltaic cell, and the photovoltaic cell is arranged in an enclosed space defined by the package compound and the two protective layers.

The present disclosure further discloses a photovoltaic module of a photovoltaic cell, which includes a conductive sheet and two photovoltaic units mutually interveningly disposed on the conductive sheet and electrically connected to each other by the conductive sheet. Each of the two photovoltaic units includes a photoelectric conversion complex layer, a conductive pillar, an insulating film, and a connecting sheet. The photoelectric conversion complex layer includes a first region, a second region, and a partition slot arranged between the first region and the second region. The first region and the second region are separated from each other and are respectively disposed on two adjacent conductive sheets. The conductive pillar is embedded in the second region. The insulating film is disposed on the first region and the second region and is arranged across the partition slot. The connecting sheet is disposed on the first region and the second region and is connected to the conductive pillar. The insulating film is embedded in the connecting sheet. The first region and the second region respectively arranged in the two photovoltaic units and arranged adjacent to each other are disposed on the conductive sheet, and the conductive sheet is connected to the conductive pillar of the corresponding second region.

Preferably, in each of the two photovoltaic units, the second region is divided into two sub-regions by the conductive pillar embedded therein.

Preferably, a distance between the two photovoltaic units is substantially within a range of 10 μm to 120 μm, a distance between the first region and the second region is substantially within a range of 10 μm to 120 μm, and a distance between the two sub-regions is substantially within a range of 10 μm to 120 μm.

Preferably, in each of the two photovoltaic units, each of the first regions and the second regions include an electron transferring layer, an active layer stacked on the electron transferring layer, and an electronic hole transferring layer stacked on the active layer, wherein the electron transferring layer is arranged adjacent to the conductive sheet, and the electronic hole transferring layer is arranged away from the conductive sheet.

In summary, each of the photovoltaic module, the photovoltaic cell, and the photovoltaic device of the present disclosure is different from the conventional structure (e.g., the structure of the conventional photovoltaic module), thereby mass production can be easily achieved. Moreover, the structure of the photovoltaic cell can be massively manufactured by using a roll to roll (R2R) manner, thereby reducing the manufacturing difficulty and cost.

In order to further appreciate the characteristics and technical contents of the present disclosure, references are hereunder made to the detailed descriptions and appended drawings in connection with the present disclosure. However, the appended drawings are merely shown for exemplary purposes, and should not be construed as restricting the scope of the present disclosure.

### BRIEF DESCRIPTION OF THE DRAWINGS

FIG. 1 is a top planar view showing step S110 of a method for manufacturing a photovoltaic cell according to a first embodiment of the present disclosure;

FIG. 2 is a cross-sectional view taken along a cross-sectional line II-II of FIG. 1;

FIG. 3 is a top planar view showing step S120 of the method;

FIG. 4 is a cross-sectional view taken along a cross-sectional line IV-IV of FIG. 3;

FIG. 5 is a top planar view showing step S130 of the method;

FIG. 6 is a cross-sectional view taken along a cross-sectional line VI-VI of FIG. 5;

FIG. 7 is a top planar view showing step S140 of the method;

FIG. 8 is a cross-sectional view taken along a cross-sectional line VIII-VIII of FIG. 7;

FIG. 9 is a top planar view showing step S150 of the method;

FIG. 10 is a cross-sectional view taken along a cross-sectional line X-X of FIG. 9;

FIG. 11 is an enlarged view showing a portion of FIG. 10;

FIG. 12 is a cross-sectional view showing the photovoltaic cell of FIG. 10 in another structure; and

FIG. 13 is a cross-sectional view showing a photovoltaic device according to a second embodiment of the present disclosure.

### DETAILED DESCRIPTION OF THE PREFERRED EMBODIMENTS

References are hereunder made to the detailed descriptions and appended drawings in connection with the present disclosure. However, the appended drawings are merely provided for exemplary purposes, and should not be construed as restricting the scope of the present disclosure.

### First Embodiment

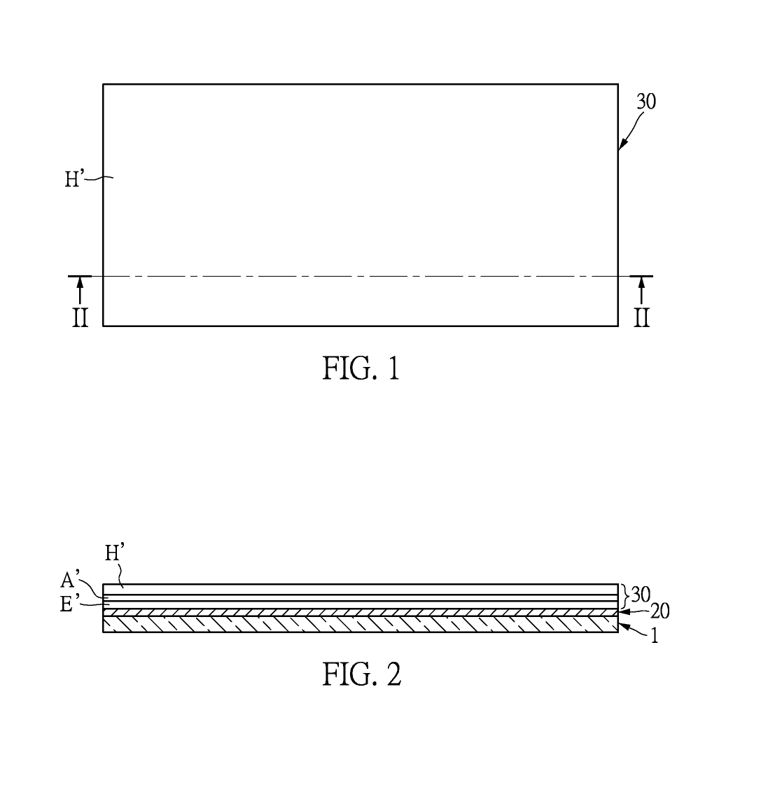

Reference is made to FIGS. 1 to 12, which illustrate a first embodiment of the present disclosure. The present embodiment discloses a photovoltaic cell 100. The following description first addresses a method for manufacturing the photovoltaic cell 100 in order to clearly describe the structure of the photovoltaic cell 100. The method of the present embodiment includes steps S110 to S150, but the manufacturing method of the photovoltaic cell 100 is not limited thereto.

Reference is made to FIGS. 1 and 2, which illustrate step S110. A conductive layer 20 and a photovoltaic layer 30 are sequentially stacked on a substrate 1, that is to say, the conductive layer 20 is sandwiched between the conductive layer 20 and the substrate 1. The photovoltaic layer 30 in the present embodiment is a multi-layer structure including an electron transferring layer E′, an active layer A′ stacked on the electron transferring layer E′, and an electronic hole transferring layer H′ stacked on the active layer A′, but the present disclosure is not limited thereto.

Moreover, the sequence or manufacturing manner of the substrate 1, the conductive layer 20, and the photovoltaic layer 30 can be adjusted or changed according to design requirements. For example, the photovoltaic layer 30 can be formed by sequentially coating the electron transferring layer E′, the active layer A′, and the electronic hole transferring layer H′ onto the conductive layer 20; or, the photovoltaic layer 30 can be formed by sequentially coating the electronic hole transferring layer H′, the active layer A′, and the electron transferring layer E′ onto the conductive layer 20. Before step S110, the substrate 1 and/or the conductive layer 20 provided by the present disclosure can be rolled in a cylindrical structure.

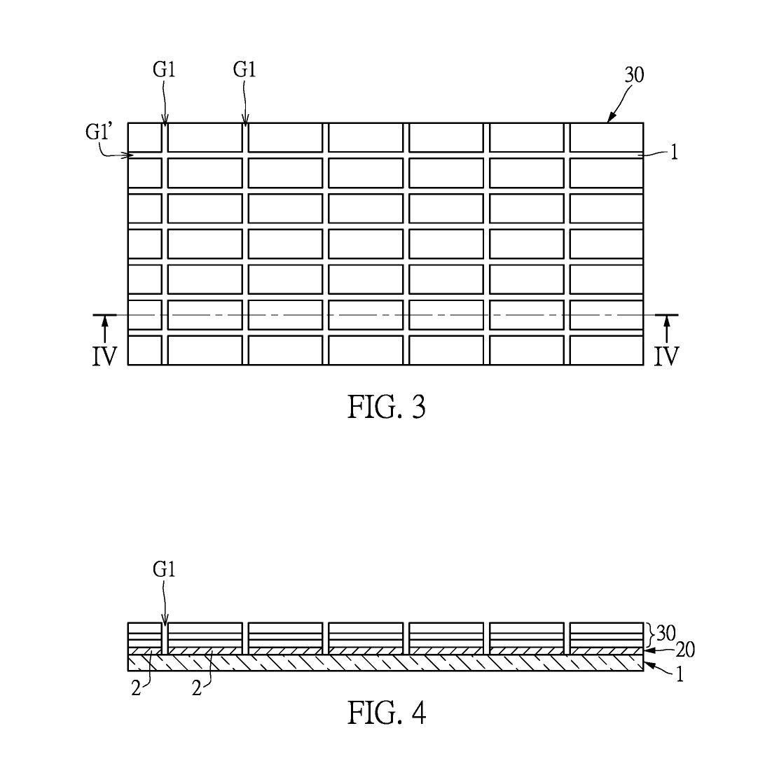

Reference is made to FIGS. 3 and 4, which illustrate step S120. The photovoltaic layer 30 and the conductive layer 20 are etched to form a plurality of first longitudinal etching slots G1 and a plurality of first transversal etching slots G1′, which are in a criss-cross arrangement (i.e., a fence shape). The etching of step S120 preferably does not damage the substrate 1. In practical application, the substrate 1 can be etched, but cannot be etched there-through. Moreover, the first longitudinal etching slots G1 and the first transversal etching slots G1′ are formed by penetrating through the photovoltaic layer 30 and the conductive layer 20 so as to expose a part of the substrate 1. That is to say, the part of the substrate 1 is regarded as the bottoms of the first longitudinal etching slots G1 and the first transversal etching slots G1′.

Specifically, step S120 is preferably implemented by using a specific laser beam, which does not damage the substrate 1, and the first longitudinal etching slots G1 and the first transversal etching slots Gr each have a width within a range of 10 μm to 120 μm. Moreover, the conductive layer 20 is divided into a plurality of conductive sheets 2, which are in a first matrix arrangement, by the first longitudinal etching slots G1 and the first transversal etching slots G1′.

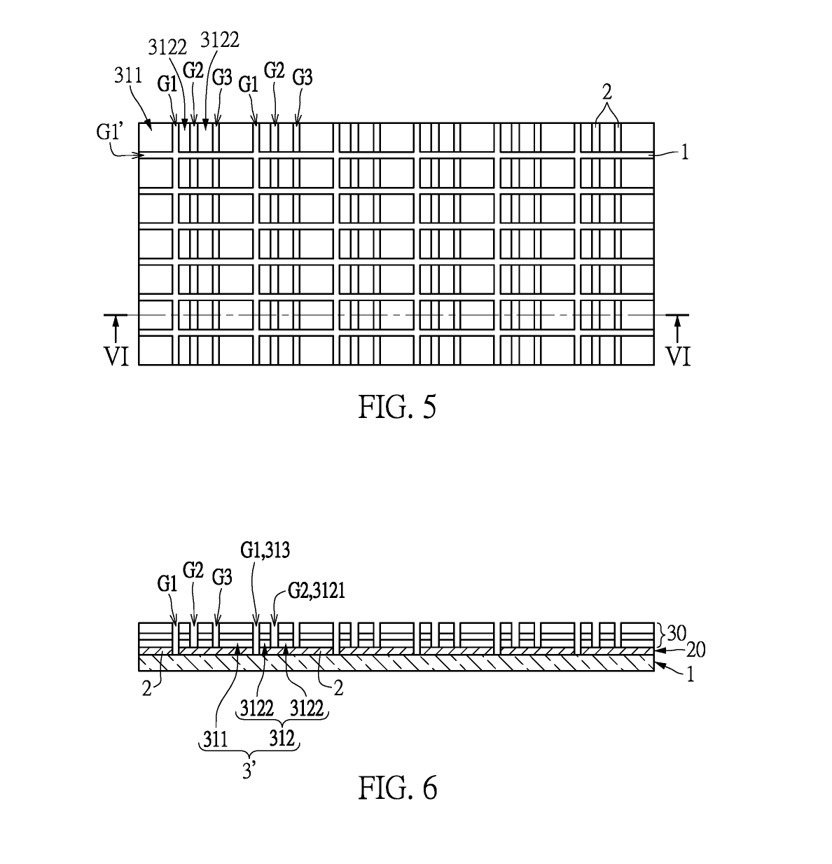

Reference is made to FIGS. 5 and 6, which illustrate step S130. The photovoltaic layer 30 is etched to form a second etching slot G2 and a third etching slot G3, which are spaced apart from (and parallel to) each other and are sequentially arranged at one side of each of the first longitudinal etching slots G1. Each of the first longitudinal etching slots G1 is parallel to the adjacent second and third etching slots G2, G3.

The etching of step S130 preferably does not damage the conductive layer 20. In practical application, the conductive layer 20 can be etched, but cannot be etched there-through. Moreover, the second etching slots G2 and the third etching slots G3 are formed by penetrating through the photovoltaic layer 30 so as to expose a part of the conductive layer 20 (or the conductive sheets 2). That is to say, the part of the conductive layer 20 (or the conductive sheets 2) is regarded as the bottoms of the second etching slots G2 and the third etching slots G3.

Specifically, step S130 is preferably implemented by using a specific laser beam, which does not damage the conductive layer 20, and the second etching slots G2 and the third etching slots G3 each have a width within a range of 10 μm to 120 μm. Moreover, the photovoltaic layer 30 is divided into a plurality of photovoltaic unit precursors 3′, which are in a second matrix arrangement different from the first matrix arrangement, by the second etching slots G2 and the third etching slots G3.

In more detail, in each of the photovoltaic unit precursors 3′, a part of the first longitudinal etching slot G1 penetrating through the photovoltaic layer 30 and the conductive layer 20 is defined as a partition slot 313, and the photovoltaic unit precursor 3′ includes a first region 311 and a second region 312 arranged at two opposite sides of the partition slot 313 (i.e., the left side and the right side of the partition slot 313 as shown in FIG. 6); a part of the second etching slot G2 penetrating through the second region 312 is defined as a filling slot 3121 corresponding in position to one of the conductive sheets 2, and the second region 312 includes two sub-regions 3122 arranged at two opposite sides of the filling slot 3121.

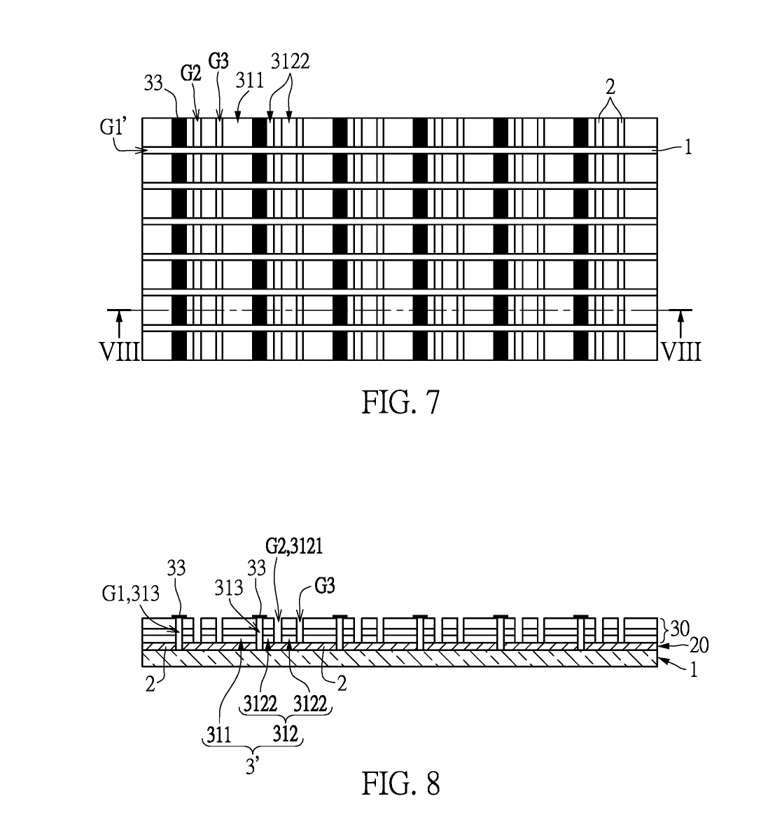

Reference is made to FIGS. 7 and 8, which illustrate step S140. For each of the photovoltaic unit precursors 3′, an insulating film 33 is formed on the first region 311 and the second region 312 and is arranged across the partition slot 313, but the insulating film 33 does not cover the filling slot 3121. The insulating films 33 can be formed by using a screen printing manner, and the insulating films 33 can be made of a UV glue, an epoxy, or a blue glue, but the present disclosure is not limited thereto.

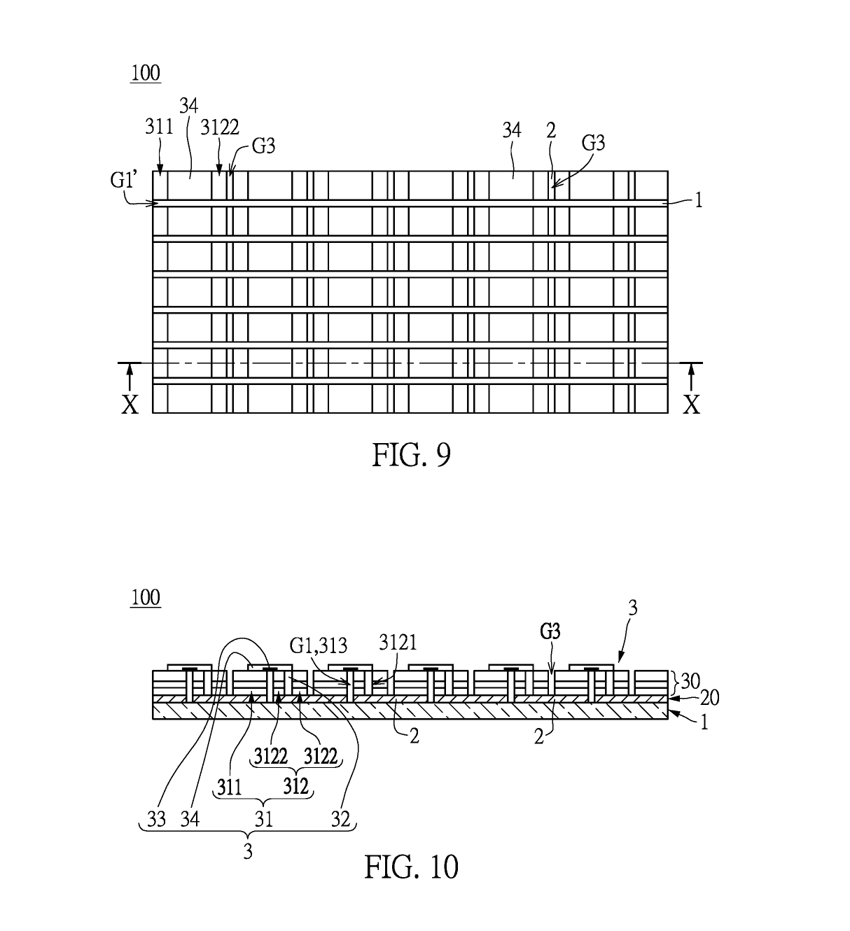

Reference is made to FIGS. 9 and 10, which illustrate step S150. For each of the photovoltaic unit precursors 3′, a conductive pillar 32 is formed in the filling slot 3121, a connecting sheet 34 is formed on the first region 311 and the second region 312, and the connecting sheet 34 is connected to the conductive pillar 32 and entirely covers the insulating film 33. Accordingly, each of the photovoltaic unit precursors 3′, the corresponding insulating film 33, the corresponding conductive pillar 32, and the corresponding connecting sheet 34 jointly define as a photovoltaic unit 3. Moreover, in each row of the photovoltaic units 3, an electrical connection of any two adjacent photovoltaic units 3 is established by being connected to one of the conductive sheets 2. It should be noted that the conductive pillar 32 and the connecting sheet 34 of each of the photovoltaic units 3 in the present embodiment can be integrally formed as an one-piece structure or independently formed, but the present disclosure is not limited thereto.

The manufacturing method of the photovoltaic cell 100 has been disclosed in the above description, and the following description will address the structural features of the photovoltaic cell 100 of the present embodiment. As shown in FIGS. 9 to 11, the photovoltaic cell 100 includes a substrate 1, a plurality of conductive sheets 2, and a plurality of photovoltaic units 3. The conductive sheets 2 are separately disposed on the substrate 1 in a first matrix arrangement. The photovoltaic units 3 are mutually interveningly disposed on the conductive sheets 2 and form a second matrix arrangement different from the first matrix arrangement. Moreover, any two adjacent rows of the second matrix arrangement of the photovoltaic units 3 are separated from each other, and a distance between any two adjacent photovoltaic units 3 is substantially within a range of 10 μm to 120 μm. In each row of the photovoltaic units 3, an electrical connection of any two adjacent photovoltaic units 3 is established by being connected to one of the conductive sheets 2.

Specifically, the substrate 1 can be a translucent resin plate or a translucent glass plate, and the material of the translucent resin plate includes at least one of a polyethylene terephthalate (PET), a polyethylene (PE), a polyimide (PI), a polyamide (PA), a polyurethane (PU), and an acrylic. Each of the conductive sheets 2 is transparent and is made of an organic conductive material or an inorganic conductive material. The organic conductive material includes a poly 3,4-ethylenedioxythiophene (PEDOT), carbon nanotubes, or a combination thereof, and the inorganic conductive material includes a metal or a metal oxide.

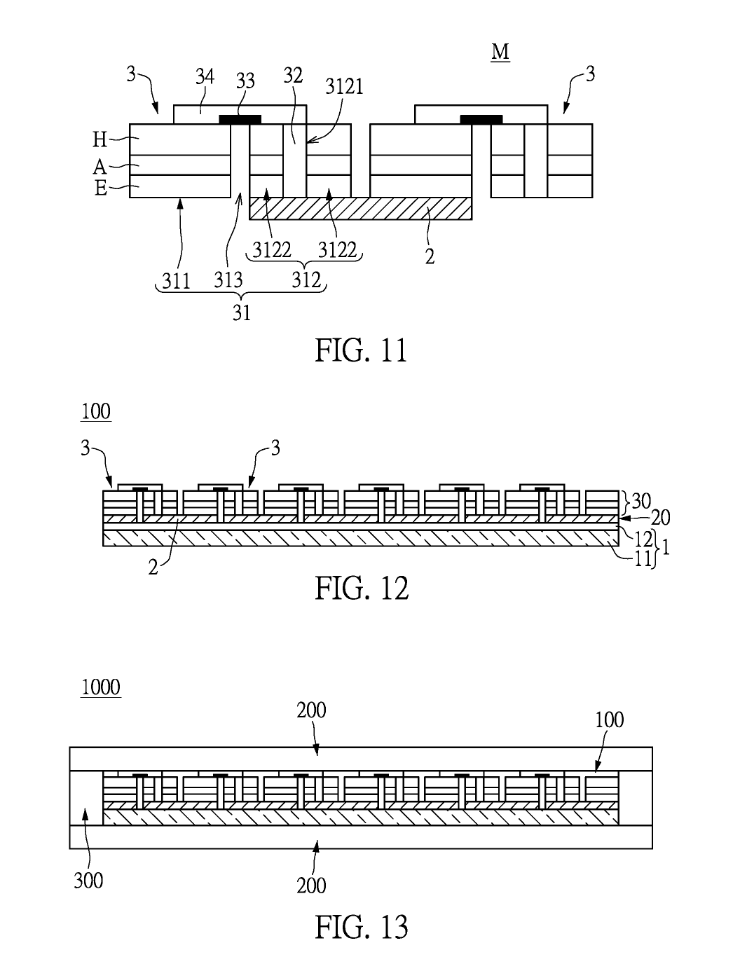

As shown in FIGS. 10 and 11, each of the photovoltaic units 3 includes a photoelectric conversion complex layer 31, a conductive pillar 32 embedded in the photoelectric conversion complex layer 31, an insulating film 33 disposed on a top surface of the photoelectric conversion complex layer 31, and a connecting sheet 34 covering the insulating film 33 and connected to the conductive pillar 32. Due to the fact that the photovoltaic units 3 are of the same structure, the following description will focus on the structure of just one of the photovoltaic units 3 for the sake of brevity.

The photoelectric conversion complex layer 31 includes a first region 311, a second region 312, and a partition slot 313 arranged between the first region 311 and the second region 312. The first region 311 and the second region 312 are arranged at two opposite sides of the partition slot 313 (i.e., the left side and the right side of the partition slot 313 as shown in FIG. 10). The partition slot 313 exposes from a part of the substrate 1, that is to say, it can be regarded that the bottom of the partition slot 313 is a part of the substrate 1. The first region 311 and the second region 312 of the photoelectric conversion complex layer 31 are separated from each other and are respectively disposed on two adjacent conductive sheets 2, which are arranged at the two opposite sides of the partition slot 313. A distance between the first region 311 and the second region 312 in the present embodiment is substantially within a range of 10 μm to 120 μm, but the present disclosure is not limited thereto.

In more detail, each of the first region 311 and the second region 312 includes an electron transferring layer E, an active layer A stacked on the electron transferring layer E, and an electronic hole transferring layer H stacked on the active layer A. The electron transferring layer E, the active layer A, and the electronic hole transferring layer H are sequentially stacked in a direction away from the substrate 1 (i.e., the direction is from bottom to tp as shown in FIG. 11). The electron transferring layer E can be made of a material such as ZnO or TiO₂, which can promote the injection and transmission of electrons. The electronic hole transferring layer H can be made of a material such as PEDOT, MoO₃, or V₂O₅, which can promote the injection and transmission of electronic holes. The active layer A can be made of a material that can promote re-combination of electrons and electronic holes, and the active layer A can be a bulk-heterojunction (BHJ) single layer structure. However, the arrangement and material of the electron transferring layer E, the active layer A, and the electronic hole transferring layer H in the present disclosure are not limited to the present embodiment. In other embodiments of the present disclosure, the electronic hole transferring layer H, the active layer A, and the electron transferring layer E are sequentially stacked in a direction away from the substrate 1.

The conductive pillar 32 is embedded in the second region 312 and is connected to the corresponding conductive sheet 2. The second region 312 is divided into two sub-regions 3122 by the conductive pillar 32 embedded therein, and a distance between the two sub-regions 3122 is substantially within a range of 10 μm to 120 μm.

The insulating film 33 is disposed on the first region 311 and the second region 312 and is arranged across the partition slot 313, and the insulating film 33 does not contact the conductive pillar 32. Specifically, the insulating film 33 is disposed on the first region 311 and one of the two sub-regions 3122 of the second region 312, the latter one of which is arranged adjacent to the first region 311, and an opening of the partition slot 313 away from the substrate 1 is substantially shielded by the insulating film 33.

The connecting sheet 34 is disposed on the first region 311 and the second region 312 and is connected to the conductive pillar 32, and the insulating film 33 is embedded in the connecting sheet 34. In more detail, the connecting sheet 34 is disposed on the first region 311 and one of the two sub-regions 3122 of the second region 312, the latter one of which is arranged adjacent to the first region 311.

The structure of the photovoltaic unit 3 of the present embodiment has been disclosed in the above description. For each row of the photovoltaic units 3 of the photovoltaic cell 100, the first region 311 of one of any two adjacent photovoltaic units 3 and the second region 312 of the other photovoltaic unit 3 are arranged adjacent to each other, and are disposed on one of the conductive sheets 2.

Moreover, each conductive sheet 2 and two adjacent photovoltaic units 3 mutually interveningly disposed thereon can jointly define as a photovoltaic module M (as shown in FIG. 11), and the two adjacent photovoltaic units 3 are electrically connected to each other by the corresponding conductive sheet 2. In addition, the photovoltaic module M can be independently applied to other photovoltaic cells (not shown), that is to say, the photovoltaic module M is not limited to be applied to the photovoltaic cell 100 as shown in FIG. 10.

The photovoltaic cell 100 of the present embodiment is disclosed as shown in FIG. 10, but the photovoltaic cell 100 can be adjusted according to practical design requirements. For example, as shown in FIG. 12, the substrate 1 includes a plate 11 and a hardened layer 12 disposed on the plate 11, and the conductive sheets 2 are disposed on the hardened layer 12.

Specifically, the plate 11 is a translucent resin plate or a translucent glass plate, and the material of the translucent resin plate includes at least one of a polyethylene terephthalate (PET), a polyethylene (PE), a polyimide (PI), a polyamide (PA), a polyurethane (PU), and an acrylic. The material of the hardened layer 12 includes at least one of an acrylic, an epoxy, and a silica, and the hardened layer 12 has a thickness within a range of 1 μm to 5 μm.

### Second Embodiment

Reference is made to FIG. 13, which illustrates a second embodiment of the present disclosure. The present embodiment discloses a photovoltaic device 1000 including the photovoltaic cell 100 of the first embodiment, two protective layers 200, and a package compound 300. The photovoltaic cell 100 has been described in the first embodiment, so that the present embodiment will not describe the structure features of the photovoltaic cell 100 again.

Moreover, the two protective layers 200 are respectively disposed on two opposite sides of the photovoltaic cell 100 (i.e., the top side and the bottom side of the photovoltaic cell 100 as shown in FIG. 13). The package compound 300 is formed to connect the two protective layers 200 and is arranged around the photovoltaic cell 100, such that the photovoltaic cell 100 can be arranged in an enclosed space defined by the package compound 300 and the two protective layers 200.

Specifically, the package compound 300 can be made of a heat-sensitive sealing resin material or an UV-sensitive sealing resin material, and the package compound 300 is formed in a continuous ring-shaped structure around the outer side of the photovoltaic cell 100. Each of the two protective layers 200 can be a transparent plastic layer or a glass layer, and the material of the transparent plastic layer includes at least one of a polyethylene terephthalate (PET), a polyethylene (PE), a polyimide (PI), a polyamide (PA), a polyurethane (PU), and an acrylic, but the present disclosure is not limited thereto.

Accordingly, the photovoltaic cell 100 can be substantially sealed by the package compound 300 and the two protective layers 200, and only allows a portion of the wires (not shown) of the photovoltaic cell 100 to be exposed, so that the reliability (e.g., a heat-resistant property, a low-temperature resistant property, a moisture resistant property, or weather resistant property) of the photovoltaic device 1000 can be increased.

### The Effects Associated with the Present Embodiments

In summary, each of the photovoltaic module, the photovoltaic cell, and the photovoltaic device of the present embodiments is different from the conventional structure (e.g., the structure of the conventional photovoltaic module), thereby mass production can be easily achieved. Moreover, the structure of the photovoltaic cell can be massively manufactured by using a roll to roll (R2R) manner, thereby reducing the manufacturing difficulty and cost.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. A photovoltaic cell, comprising:
a substrate;
a plurality of conductive sheets mutually interveningly disposed on the substrate and forming a first matrix arrangement; and
a plurality of photovoltaic units mutually interveningly disposed on the conductive sheets and forming a second matrix arrangement different from the first matrix arrangement;
wherein any two adjacent rows of the second matrix arrangement of the photovoltaic units are separated from each other;
wherein in each row of the photovoltaic units, an electrical connection of any two adjacent photovoltaic units is established by being connected to one of the conductive sheets.

2. The photovoltaic cell as claimed in claim 1, wherein each of the photovoltaic units includes:
a photoelectric conversion complex layer including a first region, a second region, and a partition slot arranged between the first region and the second region, wherein the first region and the second region are separated from each other and are respectively disposed on two adjacent conductive sheets;
a conductive pillar embedded in the second region and connected to the corresponding conductive sheet;
an insulating film disposed on the first region and the second region and arranged across the partition slot; and
a connecting sheet disposed on the first region and the second region and connected to the conductive pillar, wherein the insulating film is embedded in the connecting sheet.

3. The photovoltaic cell as claimed in claim 2, wherein the first region and the second region respectively arranged in any two adjacent photovoltaic units and arranged adjacent to each other are disposed on the one of the conductive sheets.

4. The photovoltaic cell as claimed in claim 2, wherein in each of the photovoltaic units, the second region is divided into two sub-regions by the conductive pillar embedded therein, and a distance between the two sub-regions is substantially within a range of 10 μm to 120 μm.

5. The photovoltaic cell as claimed in claim 2, wherein in each of the photovoltaic units, a distance between the first region and the second region is substantially within a range of 10 μm to 120 μm, and each of the first regions and the second regions include an electron transferring layer, an active layer stacked on the electron transferring layer, and an electronic hole transferring layer stacked on the active layer.

6. The photovoltaic cell as claimed in claim 1, wherein a distance between any two adjacent photovoltaic units is substantially within a range of 10 μm to 120 μm.

7. The photovoltaic cell as claimed in claim 1, wherein the substrate includes a plate and a hardened layer disposed on the plate, and the conductive sheets are disposed on the hardened layer.

8. The photovoltaic cell as claimed in claim 7, wherein the plate is a translucent resin plate or a translucent glass plate, and the material of the translucent resin plate includes at least one of a polyethylene terephthalate (PET), a polyethylene (PE), a polyimide (PI), a polyamide (PA), a polyurethane (PU), and an acrylic.

9. The photovoltaic cell as claimed in claim 7, wherein the material of the hardened layer includes at least one of an acrylic, an epoxy, and a silica, and the hardened layer has a thickness within a range of 1 μm to 5 μm.

10. The photovoltaic cell as claimed in claim 1, wherein each of the conductive sheets is transparent and is made of an organic conductive material or an inorganic conductive material, wherein the organic conductive material includes a poly 3,4-ethylenedioxythiophene (PEDOT), carbon nanotubes, or a combination thereof, and the inorganic conductive material includes a metal or a metal oxide.

11. A photovoltaic device, comprising:
a photovoltaic cell including:
a substrate;
a plurality of conductive sheets mutually interveningly disposed on the substrate and forming a first matrix arrangement; and
a plurality of photovoltaic units mutually interveningly disposed on the conductive sheets and forming a second matrix arrangement different from the first matrix arrangement,
wherein any two adjacent rows of the second matrix arrangement of the photovoltaic units are separated from each other; and in each row of the photovoltaic units, an electrical connection of any two adjacent photovoltaic units is established by being connected to one of the conductive sheets;
two protective layers respectively disposed on two opposite sides of the photovoltaic cell; and
a package compound connecting the two protective layers and arranged around the photovoltaic cell, and the photovoltaic cell is arranged in an enclosed space defined by the package compound and the two protective layers.

12. A photovoltaic module of a photovoltaic cell, comprising:
a conductive sheet; and
two photovoltaic units mutually interveningly disposed on the conductive sheet and electrically connected to each other by the conductive sheet, each of the two photovoltaic units including:
a photoelectric conversion complex layer including a first region, a second region, and a partition slot arranged between the first region and the second region, wherein the first region and the second region are separated from each other and are respectively disposed on two adjacent conductive sheets;
a conductive pillar embedded in the second region;
an insulating film disposed on the first region and the second region and arranged across the partition slot; and
a connecting sheet disposed on the first region and the second region and connected to the conductive pillar, wherein the insulating film is embedded in the connecting sheet;
wherein the first region and the second region respectively arranged in the two photovoltaic units and arranged adjacent to each other are disposed on the conductive sheet, and the conductive sheet is connected to the conductive pillar of the corresponding second region.

13. The photovoltaic module as claimed in claim 12, wherein in each of the two photovoltaic units, the second region is divided into two sub-regions by the conductive pillar embedded therein.

14. The photovoltaic module as claimed in claim 13, wherein a distance between the two photovoltaic units is substantially within a range of 10 μm to 120 μm, a distance between the first region and the second region is substantially within a range of 10 μm to 120 μm, and a distance between the two sub-regions is substantially within a range of 10 μm to 120 μm.

15. The photovoltaic module as claimed in claim 12, wherein in each of the two photovoltaic units, each of the first regions and the second regions include an electron transferring layer, an active layer stacked on the electron transferring layer, and an electronic hole transferring layer stacked on the active layer, wherein the electron transferring layer is arranged adjacent to the conductive sheet, and the electronic hole transferring layer is arranged away from the conductive sheet.
